(19) United States
(12) Patent Application Publication
(10) Pub. No.: US 2021/0083223 A1
(43) Pub. Date: Mar. 18, 2021

(54) ORGANIC LIGHT EMITTING DIODE DISPLAY PANEL AND ORGANIC LIGHT EMITTING DIODE DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Tianfu GUO, Wuhan, Hubei (CN)

(21) Appl. No.: 16/481,484

(22) PCT Filed: Jul. 10, 2019
(86) PCT No.: PCT/CN2019/095342

§ 371 Date: Jul. 29, 2019

(30) Foreign Application Priority Data
Jun. 4, 2018 (CN) 201810563204.4

(51) Int. Cl. H01L 51/52

(52) U.S. Cl. CPC H01L 51/5253; H01L 27/3244

(57) ABSTRACT

The OLED display panel and display device include: a light emitting substrate, and at least one set of encapsulation film disposed on the light emitting substrate; the encapsulation film includes a first inorganic layer disposed on the light emitting substrate, and a retaining wall is provided in an edge region of the first inorganic layer, and an organic layer is disposed on the first inorganic layer, and the organic layer is retained in the retaining wall, and a second inorganic layer covering the first inorganic layer, the organic layer and the retaining wall is provided on the organic layer; the retaining wall is configured as a sawtooth structure.

### FIELD OF THE INVENTION

The present application relates to a display technology field, and more particularly to an organic light emitting diode display panel and an organic light emitting diode display device.

### BACKGROUND OF THE INVENTION

OLED (Organic Light Emitting Diode) is widely used and concerned as current type light emitting device because of its self-illumination, rich color, fast response, wide viewing angle, light weight and flexible display.

Since the edge of the OLED device is easily invaded by water and oxygen, resulting in phenomena such as electrode oxidation, poor chemical reaction of organic materials or black spots, and the service life of the OLED device may be reduced. In the existing encapsulation, a material which can improve the water and oxygen barrier performance of the OLED device is generally disposed at the edge of the OLED device. However, this will result in a larger frame of the OLED display panel.

### SUMMARY OF THE INVENTION

The technical problem mainly solved by this application is to improve the water and oxygen barrier performance of the OLED display panel and meanwhile to reduce the frame of the OLED display panel.

First, the present application provides an organic light emitting diode (OLED) display panel, including:

a light emitting substrate, and at least one set of encapsulation film disposed on the light emitting substrate;

wherein each set of the encapsulation films includes a first inorganic layer disposed on the light emitting substrate, and a retaining wall is provided in an edge region of the first inorganic layer, and an organic layer is disposed on the first inorganic layer, and the organic layer is retained in the retaining wall, and a second inorganic layer covering the first inorganic layer, the organic layer and the retaining wall is provided on the organic layer;

wherein the retaining wall is configured as a sawtooth structure capable of improving water and oxygen barrier performance of the OLED display panel, and a distance between the retaining wall and an edge of the OLED display panel is between 0 mm and 1 mm, and a material of the retaining wall is iron oxide, titanium oxide, silicon oxide, copper or cerium oxide.

In the OLED display panel of the present application, the OLED display panel further includes a barrier layer, and the barrier layer is disposed on the retaining wall, and the barrier layer covers the retaining wall.

In the OLED display panel of the present application, the retaining wall includes a main body portion and a plurality of protrusions;

wherein the main body portion is disposed on the light emitting substrate, and the plurality of protrusions are connected to the main body portion and are spaced apart on the main body portion.

In the OLED display panel of the present application, the retaining wall includes a plurality of sub-retaining walls, and the plurality of sub-retaining walls are spaced apart on the light emitting substrate to form the sawtooth structure retaining wall surrounding the organic layer on the light emitting substrate.

In the OLED display panel of the present application, a cross section of the plurality of sub-retaining walls is trapezoidal, rectangular or triangular.

In the OLED display panel of the present application, shapes and sizes of the plurality of sub-retaining walls are consistent.

In the OLED display panel of the present application, the light emitting substrate includes a substrate, an insulating layer, a device layer and a light emitting layer, which are stacked.

Second, the present application provides an organic light emitting diode (OLED) display panel, including:

a light emitting substrate, and at least one set of encapsulation film disposed on the light emitting substrate;

wherein each set of the encapsulation films includes a first inorganic layer disposed on the light emitting substrate, and a retaining wall is provided in an edge region of the first inorganic layer, and an organic layer is disposed on the first inorganic layer, and the organic layer is retained in the retaining wall, and a second inorganic layer covering the first inorganic layer, the organic layer and the retaining wall is provided on the organic layer;

wherein the retaining wall is configured as a sawtooth structure capable of improving water and oxygen barrier performance of the OLED display panel.

In the OLED display panel of the present application, the OLED display panel further includes a barrier layer, and the barrier layer is disposed on the retaining wall, and the barrier layer covers the retaining wall.

In the OLED display panel of the present application, the retaining wall includes a main body portion and a plurality of protrusions;

wherein the main body portion is disposed on the light emitting substrate, and the plurality of protrusions are connected to the main body portion and are spaced apart on the main body portion.

In the OLED display panel of the present application, the retaining wall includes a plurality of sub-retaining walls, and the plurality of sub-retaining walls are spaced apart on the light emitting substrate to form the sawtooth structure retaining wall surrounding the organic layer on the light emitting substrate.

In the OLED display panel of the present application, a cross section of the plurality of sub-retaining walls is trapezoidal, rectangular or triangular.

In the OLED display panel of the present application, shapes and sizes of the plurality of sub-retaining walls are consistent.

In the OLED display panel of the present application, a material of the barrier layer is iron oxide, titanium oxide, silicon oxide, copper or cerium oxide.

In the OLED display panel of the present application, the light emitting substrate includes a substrate, an insulating layer, a device layer and a light emitting layer, which are stacked.

Third, the present application provides an organic light emitting diode (OLED) display device, including an organic light emitting diode (OLED) display panel; wherein the OLED display panel includes:

a light emitting substrate, and at least one set of encapsulation film disposed on the light emitting substrate;

wherein each set of the encapsulation films includes a first inorganic layer disposed on the light emitting substrate, and a retaining wall is provided in an edge region of the first inorganic layer, and an organic layer is disposed on the first inorganic layer, and the organic layer is retained in the retaining wall, and a second inorganic layer covering the first inorganic layer, the organic layer and the retaining wall is provided on the organic layer;

wherein the retaining wall is configured as a sawtooth structure capable of improving water and oxygen barrier performance of the OLED display panel. In the OLED display device of the present application, the OLED display panel further includes a barrier layer, and the barrier layer is disposed on the retaining wall, and the barrier layer covers the retaining wall.

In the OLED display device of the present application, the retaining wall includes a main body portion and a plurality of protrusions;

wherein the main body portion is disposed on the light emitting substrate, and the plurality of protrusions are connected to the main body portion and are spaced apart on the main body portion.

In the OLED display device of the present application, the retaining wall includes a plurality of sub-retaining walls, and the plurality of sub-retaining walls are spaced apart on the light emitting substrate to form the sawtooth structure retaining wall surrounding the organic layer on the light emitting substrate.

In the OLED display device of the present application, a cross section of the plurality of sub-retaining walls is trapezoidal, rectangular or triangular.

The benefits of the present application are: by providing the sawtooth structure retaining wall on the OLED display panel, it not only improves the water and oxygen barrier performance of the OLED display panel, but also reduces the frame of the OLED display panel.

### BRIEF DESCRIPTION OF THE DRAWINGS

In order to more clearly illustrate the embodiments of the present invention and the prior art, the following figures will be described in the embodiments and the prior art are briefly introduced. It is obvious that the drawings are only some embodiments of the present invention, those of ordinary skill in this field can obtain other figures according to these figures without paying the premise.

FIG. 1 is a cross-sectional view diagram of the first embodiment of an organic light emitting diode (OLED) display panel provided by the present application;

FIGS. 2 to 4 are cross-sectional view diagrams of the first embodiment of forming a barrier layer in an OLED display panel provided by the present application;

FIG. 5 is a cross-sectional view diagram of the first embodiment of a retaining wall in an OLED display panel provided by the present application;

FIG. 6 is a cross-sectional view diagram of the second embodiment of a retaining wall in an OLED display panel provided by the present application; and

FIG. 7 is a cross-sectional view diagram of the second embodiment of an organic light emitting diode (OLED) display panel provided by the present application.

### DETAILED DESCRIPTION OF PREFERRED EMBODIMENTS

The embodiments of the present application are described in detail below, and the examples of the embodiments are illustrated in the drawings, wherein the same or similar reference numerals are used to refer to the same or similar elements or elements having the same or similar functions. The embodiments described below with reference to the drawings are intended to be illustrative for the present application and are not to be construed as limitation.

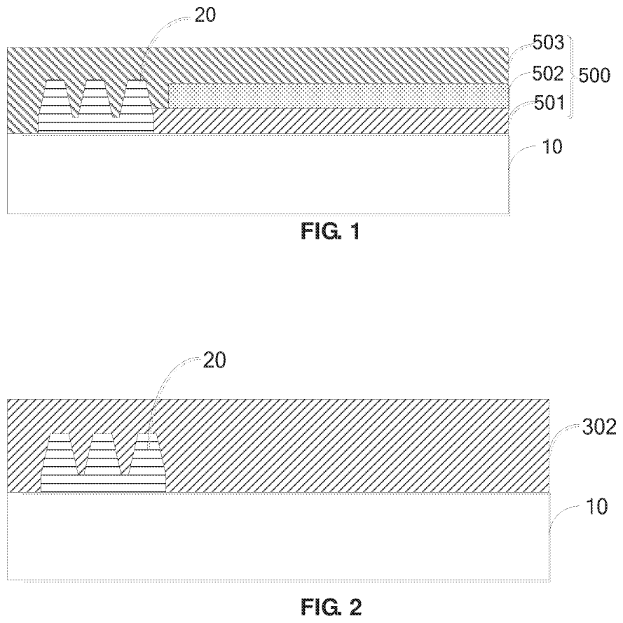

Please refer to FIG. 1. FIG. 1 is a cross-sectional view diagram of the first embodiment of an organic light emitting diode (OLED) display panel provided by the present application.

The embodiment of the present application provides an organic light emitting diode (OLED) display panel, including:

a light emitting substrate 10, and at least one set of encapsulation film 500 disposed on the light emitting substrate.

Each set of the encapsulation films 500 includes a first inorganic layer 501 disposed on the light emitting substrate 10, and a retaining wall 20 is provided in an edge region of the first inorganic layer 501. An organic layer 502 is disposed on the first inorganic layer 501, and the organic layer 502 is retained in the retaining wall 20. A second inorganic layer 503 covering the first inorganic layer 501, the organic layer 502 and the retaining wall 20 is provided on the organic layer 502.

The retaining wall 20 is configured as a sawtooth structure capable of improving water and oxygen barrier performance of the OLED display panel.

Specifically, the light emitting substrate 10 may be a glass substrate formed with a polyimide (PI), a thin film transistor (TFT) device and an organic light emitting layer. Optionally, at least one set of encapsulation film 500 is disposed on the light emitting substrate 10. The encapsulation film 500 can be a first inorganic layer 501, an organic layer 502 and a second inorganic layer 503, which are stacked on the light emitting substrate 10. Preferably, each set of the encapsulation films 500 includes a first inorganic layer 501 disposed on the light emitting substrate 10. A retaining wall 20 is provided in an edge region of the first inorganic layer 501. An organic layer 502 is disposed on the first inorganic layer, and the organic layer 502 is retained in the retaining wall 20. A second inorganic layer 503 covering the first inorganic layer 501, the organic layer 502 and the retaining wall 20 is provided on the organic layer 502. The retaining wall 20 is configured as a sawtooth structure capable of improving water and oxygen barrier performance of the OLED display panel.

The OLED display panel further includes a barrier layer 301. The barrier layer is disposed on the retaining wall 20, and the barrier layer 301 covers the retaining wall 20.

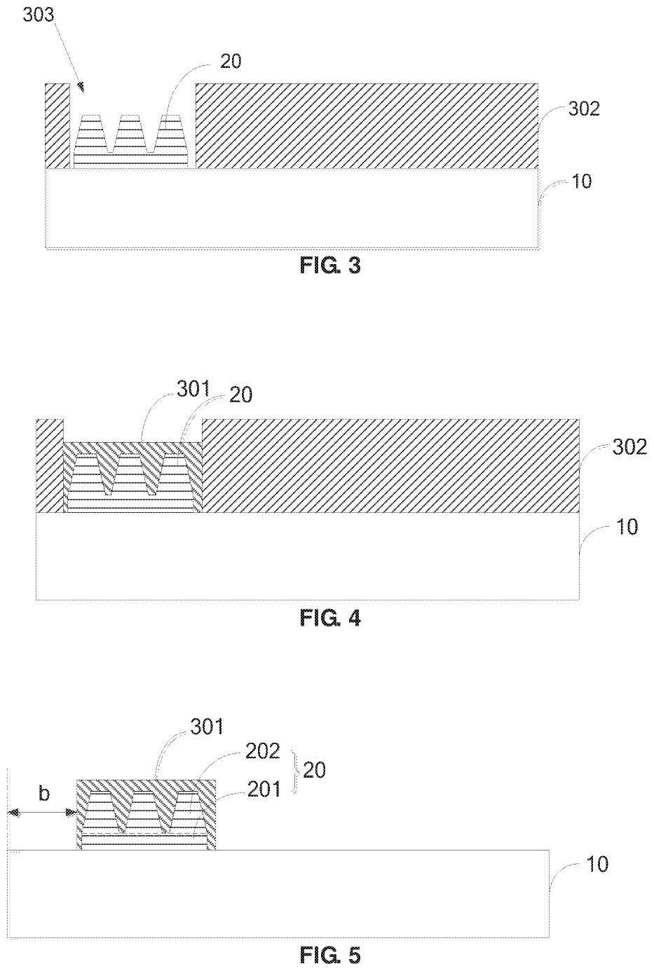

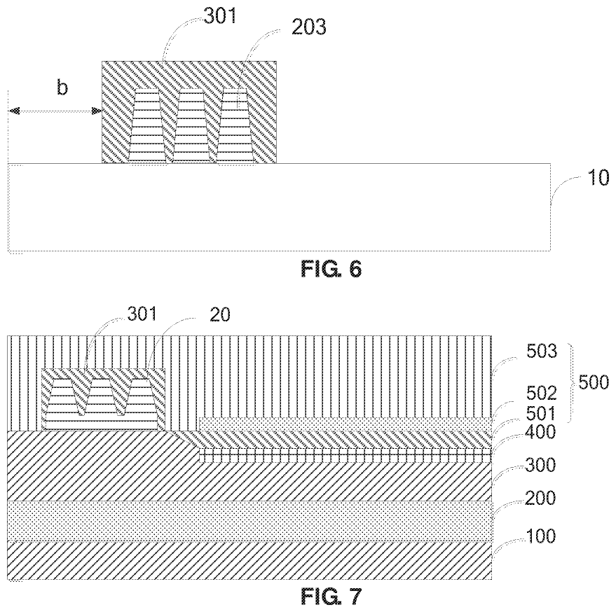

Please refer to FIG. 1, FIG. 2, FIG. 3, FIG. 4 and FIG. 5. FIGS. 2 to 4 are cross-sectional view diagrams of the first embodiment of forming a barrier layer in an OLED display panel provided by the present application. Preferably, the OLED display panel further includes a barrier layer 301. The barrier layer 301 is disposed on the retaining wall 20, and the barrier layer 301 covers the retaining wall 20. In a specific implementation, first, a barrier film 302 is coated on the light emitting substrate 10 on which the retaining wall 20 has been formed. A material of the barrier film 302 may be a hydrophobic organic compound such as polystyrene, polyalkyl or polyolefin. Then, the barrier film 302 is subjected to a process of exposure and development by a photolithography process to form a via hole 303 in the barrier film 302. The position of the via hole 303 corresponds to the position of the retaining wall 20. Then, atomic layer deposition is performed on a region corresponding to the via hole 303 to deposit a barrier layer 301 on a surface of the retaining wall 20. Preferably, the barrier layer 301 can be made of iron oxide. Finally, the barrier film 302 is removed by plasma. The aforementioned plasma contains ion electrons and neutral particles or contains ion electrons and partially free gas. A treatment gas may be oxygen, argon, an argon-hydrogen mixed gas or tetrafluoromethane.

For the process of forming the barrier layer 301, the barrier film 302 is exemplified as iron oxide. For the film formation process of iron oxide, a hydrophilic functional group such as —OH is present on the surface of the substrate. When water vapor is introduced, the surface of the substrate is tiled with a layer of water molecules. The surface of the substrate is cleaned by introducing nitrogen. Furthermore, the introduction of trimethylaluminum to the surface of the substrate causes the water molecules on the surface of the substrate to react with trimethylaluminum to form iron oxide. The nitrogen is still introduced to purge excess trimethylaluminum.

In this embodiment, since the barrier film 302 is a hydrophobic material, water vapor cannot be effectively adhered to the barrier film 302. When the inert gas purges the substrate, the water vapor is completely carried away. By the photolithography process, forming the via hole 303 in the barrier film 302 allows water vapor to adhere to the retaining wall 20 for achieving the purpose of forming the barrier layer 301 on the surface of the retaining wall 20. The objective of improving the water and oxygen barrier performance of the OLED device can be realized.

Optionally, the retaining wall 20 includes a main body portion 201 and a plurality of protrusions 202. The main body portion 201 is disposed on the light emitting substrate 10, and the plurality of protrusions 202 are connected to the main body portion 201 and are spaced apart on the main body portion 201.

Please continue to refer to FIG. 5. FIG. 5 is a cross-sectional view diagram of the first embodiment of a retaining wall in an OLED display panel provided by the present application. For instance, the retaining wall 20 includes a main body portion 201 and three protrusions 202. The main body portion 201 is disposed on the light emitting substrate 10 and connected to the light emitting substrate 10. The three protrusions 202 are spaced apart from each other on the body portion 201. Certainly, the amount of the protrusions 202 can be three, two or other numbers. Here, the three protrusions are illustrated for explanation. A distance between the retaining wall 20 and an edge of the OLED display panel is between 0 mm and 1 mm. As shown in FIG. 5, the b in the figure is the distance between the retaining wall 20 and the edge of the OLED display panel.

The surfaces of the main body portion 201 and the protrusions 202 are covered with a barrier layer 301. For the method of forming the barrier layer 301, refer to the previous embodiment, and details are not described here, again.

Specifically, the retaining wall 20, the barrier layer 301 and the second inorganic layer 503 stacked in sequence may improve the bendability of the OLED display panel.

Besides, the main body portion 201 is connected to the protrusions 202 to form the sawtooth structure retaining wall 20. The sawtooth structure retaining wall 20 does not only reduce the risk of water oxygen intrusion from the lateral side of the OLED display panel but also prevents the organic layer 502 in the encapsulation film 500 from overflowing. Therefore, the encapsulation reliability of the OLED display panel is further improved.

The retaining wall 20 includes a plurality of sub-retaining walls 203, and the plurality of sub-retaining walls 203 are spaced apart on the light emitting substrate 10 to form the sawtooth structure retaining wall 60 surrounding the organic layer 502 on the light emitting substrate 10.

Please refer to FIG. 6. FIG. 6 is a cross-sectional view diagram of the second embodiment of a retaining wall in an OLED display panel provided by the present application. For instance, the retaining wall 20 includes three sub-retaining walls 203 spaced apart from each other on the light emitting substrate 10. Moreover, the surfaces of the three sub-retaining walls 203 are disposed with the barrier layer 301. For the method of forming the barrier layer 301, please refer to the previous embodiment. Specifically, a distance between the retaining wall 20 and an edge of the OLED display panel is between 0 mm and 1 mm as shown in FIG. 6. The b in the figure is the distance between the retaining wall 20 and the edge of the OLED display panel.

In the OLED display device of the present application, a cross section of the plurality of sub-retaining walls 203 is trapezoidal, rectangular or triangular.

Shapes and sizes of the plurality of sub-retaining walls 203 are consistent.

A material of the barrier layer 301 is iron oxide, titanium oxide, silicon oxide, copper or cerium oxide.

Please refer to FIG. 7. FIG. 7 is a cross-sectional view diagram of the second embodiment of an organic light emitting diode (OLED) display panel provided by the present application. Preferably, the light emitting substrate 10 includes a substrate 100, an insulating layer 200, a device layer 300 and a light emitting layer 400, which are stacked.

For instance, the substrate 100 can be a glass substrate. Preferably, a material of the insulating layer 200 may be polyimide (PI). The device layer 300 may include a TFT device and respective film layers on the TFT device. The light emitting layer may include an anode, an organic light emitting layer and a cathode, which are stacked (all not shown in figure). The light emitting substrate 10 is similar to that in the prior art and will not be described again.

Correspondingly, the present application further provides an OLED display device, including the OLED display panel of any of the embodiments of the present application.

In this embodiment, by providing the sawtooth structure retaining wall 20 on the OLED display panel and disposing the barrier layer 301 on the retaining wall 20, it not only improves the water and oxygen barrier performance of the OLED display panel, but also reduces the frame of the OLED display panel.

The OLED display panel and display device provided by the embodiments of the present application are described in detail. The principles and implementations of the present application are described in the specific examples. The description of the above embodiments is only for helping to understand the present application. Meanwhile, those skilled in the art will be able to change the specific embodiments and the scope of the application according to the idea of the present application. In conclusion, the content of the specification should not be construed as limiting the present application.

What is claimed is:

1. An organic light emitting diode (OLED) display panel, including:
a light emitting substrate, and at least one set of encapsulation film disposed on the light emitting substrate;
wherein each set of the encapsulation films includes a first inorganic layer disposed on the light emitting substrate, and a retaining wall is provided in an edge region of the first inorganic layer, and an organic layer is disposed on the first inorganic layer, and the organic layer is retained in the retaining wall, and a second inorganic layer covering the first inorganic layer, the organic layer and the retaining wall is provided on the organic layer;
wherein the retaining wall is configured as a sawtooth structure capable of improving water and oxygen barrier performance of the OLED display panel, and a distance between the retaining wall and an edge of the OLED display panel is between 0 mm and 1 mm, and a material of the retaining wall is iron oxide, titanium oxide, silicon oxide, copper or cerium oxide.

2. The OLED display panel according to claim 1, wherein the OLED display panel further includes a barrier layer, and the barrier layer is disposed on the retaining wall, and the barrier layer covers the retaining wall.

3. The OLED display panel according to claim 2, wherein the retaining wall includes a main body portion and a plurality of protrusions;
wherein the main body portion is disposed on the light emitting substrate, and the plurality of protrusions are connected to the main body portion and are spaced apart on the main body portion.

4. The OLED display panel according to claim 2, wherein the retaining wall includes a plurality of sub-retaining walls, and the plurality of sub-retaining walls are spaced apart on the light emitting substrate to form the sawtooth structure retaining wall surrounding the organic layer on the light emitting substrate.

5. The OLED display panel according to claim 4, wherein a cross section of the plurality of sub-retaining walls is trapezoidal, rectangular or triangular.

6. The OLED display panel according to claim 5, wherein shapes and sizes of the plurality of sub-retaining walls are consistent.

7. The OLED display panel according to claim 1, wherein the light emitting substrate includes a substrate, an insulating layer, a device layer and a light emitting layer, which are stacked.

8. An organic light emitting diode (OLED) display panel, including:
a light emitting substrate, and at least one set of encapsulation film disposed on the light emitting substrate;
wherein each set of the encapsulation films includes a first inorganic layer disposed on the light emitting substrate, and a retaining wall is provided in an edge region of the first inorganic layer, and an organic layer is disposed on the first inorganic layer, and the organic layer is retained in the retaining wall, and a second inorganic layer covering the first inorganic layer, the organic layer and the retaining wall is provided on the organic layer;
wherein the retaining wall is configured as a sawtooth structure capable of improving water and oxygen barrier performance of the OLED display panel.

9. The OLED display panel according to claim 8, wherein the OLED display panel further includes a barrier layer, and the barrier layer is disposed on the retaining wall, and the barrier layer covers the retaining wall.

10. The OLED display panel according to claim 9, wherein the retaining wall includes a main body portion and a plurality of protrusions;
wherein the main body portion is disposed on the light emitting substrate, and the plurality of protrusions are connected to the main body portion and are spaced apart on the main body portion.

11. The OLED display panel according to claim 9, wherein the retaining wall includes a plurality of sub-retaining walls, and the plurality of sub-retaining walls are spaced apart on the light emitting substrate to form the sawtooth structure retaining wall surrounding the organic layer on the light emitting substrate.

12. The OLED display panel according to claim 11, wherein a cross section of the plurality of sub-retaining walls is trapezoidal, rectangular or triangular.

13. The OLED display panel according to claim 12, wherein shapes and sizes of the plurality of sub-retaining walls are consistent.

14. The OLED display panel according to claim 8, wherein a material of the barrier layer is iron oxide, titanium oxide, silicon oxide, copper or cerium oxide.

15. The OLED display panel according to claim 8, wherein the light emitting substrate includes a substrate, an insulating layer, a device layer and a light emitting layer, which are stacked.

16. An organic light emitting diode (OLED) display device, including an organic light emitting diode (OLED) display panel; wherein the OLED display panel includes:
a light emitting substrate, and at least one set of encapsulation film disposed on the light emitting substrate;
wherein each set of the encapsulation films includes a first inorganic layer disposed on the light emitting substrate, and a retaining wall is provided in an edge region of the first inorganic layer, and an organic layer is disposed on the first inorganic layer, and the organic layer is retained in the retaining wall, and a second inorganic layer covering the first inorganic layer, the organic layer and the retaining wall is provided on the organic layer;
wherein the retaining wall is configured as a sawtooth structure capable of improving water and oxygen barrier performance of the OLED display panel.

17. The OLED display device according to claim 16, wherein the OLED display panel further includes a barrier layer, and the barrier layer is disposed on the retaining wall, and the barrier layer covers the retaining wall.

18. The OLED display device according to claim 17, wherein the retaining wall includes a main body portion and a plurality of protrusions;
wherein the main body portion is disposed on the light emitting substrate, and the plurality of protrusions are connected to the main body portion and are spaced apart on the main body portion.

19. The OLED display device according to claim 17, wherein the retaining wall includes a plurality of sub-retaining walls, and the plurality of sub-retaining walls are spaced apart on the light emitting substrate to form the sawtooth structure retaining wall surrounding the organic layer on the light emitting substrate.

20. The OLED display device according to claim 17, wherein a cross section of the plurality of sub-retaining walls is trapezoidal, rectangular or triangular.
